(19) United States
(12) Patent Application Publication
(10) Pub. No.: US 2005/0141185 A1
(43) Pub. Date: Jun. 30, 2005

(54) Display enhancement device for wireless communication products

(76) Inventors: Shawn O'Neal, Santa Rosa Beach, FL (US); John Maier, Crystal Lake, IL (US)

Correspondence Address: Greenberg Traurig, LLP, 77 West Wacker Drive - Suite 2500, Chicago, IL, 60601, US

(21) Appl. No.: 10/876,136

(22) Filed: Jun. 24, 2004

Related U.S. Application Data
(60) Provisional application No. 60/480,915, filed on Jun. 24, 2003.

(51) Int. Cl. H05K 5/00

(52) U.S. Cl. 361/683

(57) ABSTRACT

A display enhancement device for a portable electronic device having a visual display, such as a cellular telephone, is provided. A magnifying lens, such as a Fresnel-type lens, is suspended above the device display by a positioning arm. The positioning arm is attached to the lens at one end, and to the device at the other end. The arm can be attached to the device and/or lens by means such as a suction cup or a mounting plate. One or more rotatable attachment mechanisms can be used to facilitate adjustment of the positioning arm and/or lens.

### RELATED APPLICATION

This application claims the benefit of U.S. Provisional Patent Application 60/480,915, filed on Jun. 24, 2003, which application is hereby incorporated by reference in its entirety.

### BACKGROUND OF THE INVENTION

The present invention relates in general to portable electronic devices, and specifically to a device for magnifying the display of a portable electronic device.

As portable electronic devices become capable of performing increasingly complex tasks, the quantity and quality of information that must be presented to users continues to rise. For example, while many prior cellular telephones were primarily required to display telephone numbers, battery status and antennae signal strength to users, modern cellular telephones can be used to send and receive email and digital messaging, take and display photographs, provide datebook functionality, and play video games, amongst other features.

Customers also demand increasingly compact form factors to facilitate continuous carrying of cellular telephones and other devices on one's person. As a result, many portable electronic devices are provided with small displays. The presentation of significant quantities of information on a small display may give users difficulty viewing the display and/or discomfort during use in some circumstances. Accordingly, it may be desirable to provide a device for enhancing the display of a portable electronic device. It may also be desirable to provide such a device having a relatively lightweight and compact form factor for ease of portability.

### BRIEF SUMMARY OF THE INVENTION

An apparatus for enhancing the display of a portable electronic device such as a cellular telephone is provided. A magnifying lens, such as a Fresnel-type lens, is supported above the display of an electronic device. The lens can be supported by a positioning arm attached to the electronic device by a mounting mechanism. The mounting mechanism may include a mounting base attached to the electronic device, an elongated cavity within the mounting base and open to the exterior surface of the mounting base on at least one end, and an elongated mounting arm which can be partially inserted into the cavity. The mounting arm may be rigid, while the positioning arm may be pliable to allow for adjustment of the magnifying lens position. The mounting arm may further include a slot into which the positioning arm can be inserted.

The mounting base cavity can be configured to extend completely through the mounting base, such that the cavity is open to the exterior surface of the mounting base on two ends. In such a configuration, the mounting arm can be inserted into either open end of the cavity to allow for different orientations of the positioning arm. Where the mounting base is attached to the back side of an electronic device, the positioning arm can be positioned to extend around the side of the device, or over the top of the device, to support the lens above the device display.

Various means of connecting the lens, positioning arm and mounting base can be employed. The positioning arm can optionally be attached to the lens by a suction cup. A suction cup mounting mechanism can also be used to attach the positioning arm to the electronic device.

Rotatable interconnects between the lens, positioning arm and/or mounting base can also be used. The positioning arm may include a rotatable tab adapted for insertion into a slot in the mounting arm. The positioning arm may also include a rotatable interconnect for attachment to the magnifying lens, thereby permitting ready adjustment of the lens orientation. A separable attachment between the magnifying lens and mounting arm can also be employed, whereby the magnifying lens can be interchanged, and the lens can be removed from the positioning arm such as for compact storage. A rotatable and separable attachment can be used, in which the attachment includes a snap connector, and a mounting tab into which the snap connector can be inserted. One of the snap connector and mounting tab can be attached to the magnifying lens, while the other is attached to the positioning arm.

### BRIEF DESCRIPTION OF THE DRAWINGS

FIG. 1 is a top plan view of a base plate in accordance with one embodiment of the invention.

FIG. 2 is a side perspective view of the base plate.

FIG. 3 is a front perspective view of a rigid mounting arm.

FIG. 4 is a broken away side elevation of the rigid mounting arm.

FIG. 5 is a plan view of the base plate mounted on the backside of a flip-style cellular telephone.

FIG. 6 is a plan view of the rigid mounting arm.

FIG. 7 is a side elevation of the base plate mounted on the backside of a flip-style cellular telephone.

FIG. 8 is a diagram of a front elevation view of the display enhancement device mounted on the backside of a cellular telephone.

FIG. 9 is a top plan view of a candy bar style cellular telephone without a display enhancement device attached thereto.

FIG. 10 is a top plan view of the cellular telephone of FIG. 9 having a display enhancement device mounted thereon.

FIG. 11 is a perspective view of a suction cup mounting device.

FIG. 12 is a top plan view of a display magnifier.

FIG. 13 is a top plan view of a flip-style cellular telephone in a closed orientation having a suction cup mounting device affixed thereto.

FIG. 14 is a top plan view of a flip-style cellular telephone in an open orientation having a display enhancement device mounted thereto.

FIG. 15 is a side elevation of a flip-style cellular telephone in an open orientation having a display enhancement device mounted thereto.

FIG. 16 is a bottom plan view of a candy bar style cellular telephone having a suction cup mounting device attached thereto.

FIG. 17 is a top plan view of a candy bar style cellular telephone having a display enhancement device mounted thereon.

FIG. 18 is a side elevation of a candy bar style cellular telephone having a display enhancement device mounted thereon.

FIG. 19 is a top plan view of a candy bar style cellular telephone having a display enhancement device mounted thereon.

FIG. 20 is a diagram of a further embodiment of the invention having swivel joints.

FIG. 21 is a front elevation view of a display enhancement device having swivel joints mounted on the backside of a cellular telephone.

FIG. 22 is a side elevation of a flip-style cellular telephone in an open orientation having a display enhancement device with swivel joints mounted thereto.

### DETAILED DESCRIPTION OF THE DRAWINGS

While this invention is susceptible to embodiment in many different forms, there are shown in the drawings and will be described in detail herein several specific embodiments, with the understanding that the present disclosure is to be considered as an exemplification of the principle of the invention and is not intended to limit the invention to the embodiments illustrated.

In accordance with one aspect of the invention, a display enhancement device is provided which serves to magnify the image of a display on a portable electronic device, such as a cellular telephone. The device can be used to provide the user with flexible control over the level of display magnification. The device can also be adapted to facilitate use on a wide variety of cellular telephones and/or portable electronic devices, such that a single device can be used by several users with different products. Also, a user can continue to use the device use even when upgrading or changing the cellular telephone with which the device is used.

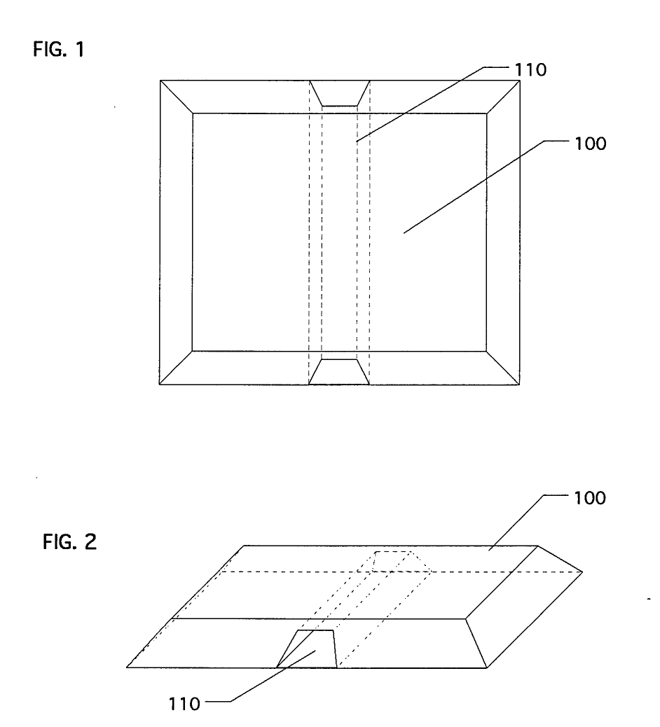

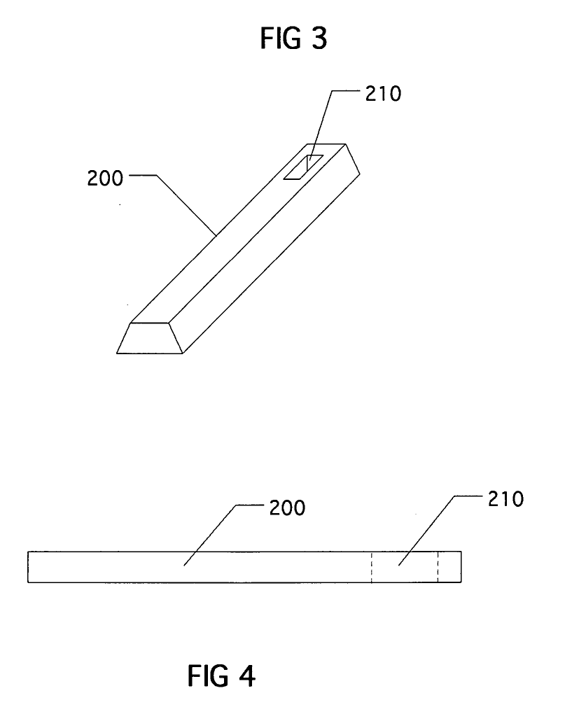

In accordance with one embodiment of the invention, the display enhancement device is comprised of a base unit, a rigid mounting arm, a pliable positioning arm and a display enhancement surface. FIG. 2 is a top plan view of base plate 100 in accordance with such an embodiment. FIG. 3 is a side perspective view of base plate 100. In the embodiment of FIGS. 1-2, base plate 100 is approximately frusto-pyramidal in shape, measuring approximately 1″×¾″×⅛″. Base plate 100 further includes cavity 110. Cavity 110 passes through base plate 100. Cavity 110 as illustrated is also approximately frusto-pyramidal in shape. Base plate 100 can be mounted to a surface of a cellular telephone or other portable electronic device with which the display enhancement device is intended for use. For example, base plate 100 can be mounted to the back surface of a cellular telephone. Such mounting can be facilitated through the provision of an adhesive substance, such as a glue or a self-stick double-backed tape, on the bottom surface of base plate 100. Base plate 100 is preferably comprised of a plastic material that resists shattering, is structurally rigid, and withstands exposure to hot and cold temperatures.

FIG. 3 is a front perspective view of rigid mounting arm 200, which is adapted to be inserted into cavity 110. In the embodiment of FIG. 3, rigid mounting arm 200 is approximately frusto-pyramidal in shape and is approximately 1/4 inch in width. The dimensions of rigid mounting arm 200 correspond roughly to the dimensions of cavity 110, such that rigid mounting arm 200 can be readily inserted and removed from cavity 110, which friction between arm 200 and the walls of cavity 110 cause mounting arm 200 to maintain its position within cavity 110 during use, once inserted therein. Furthermore, the shapes of cavity 110 and mounting arm 200 prevent arm 200 from twisting within cavity 110 once mounted therein. However, it is understood that other shapes for cavity 110 and mounting arm 200 can readily be employed.

In the embodiment of FIG. 3, Rigid mounting arm 200 further includes slot 210. Slot 210 is adapted to receive a pliable positioning arm, towards forming an operable connection between rigid mounting arm 200 and the pliable positioning arm. Slot 210 is approximately rectangular in shape, and passes through rigid mounting arm 200 from its top surface to its bottom surface. FIG. 4 is a broken away side elevation of rigid mounting arm 200, further revealing slot 210.

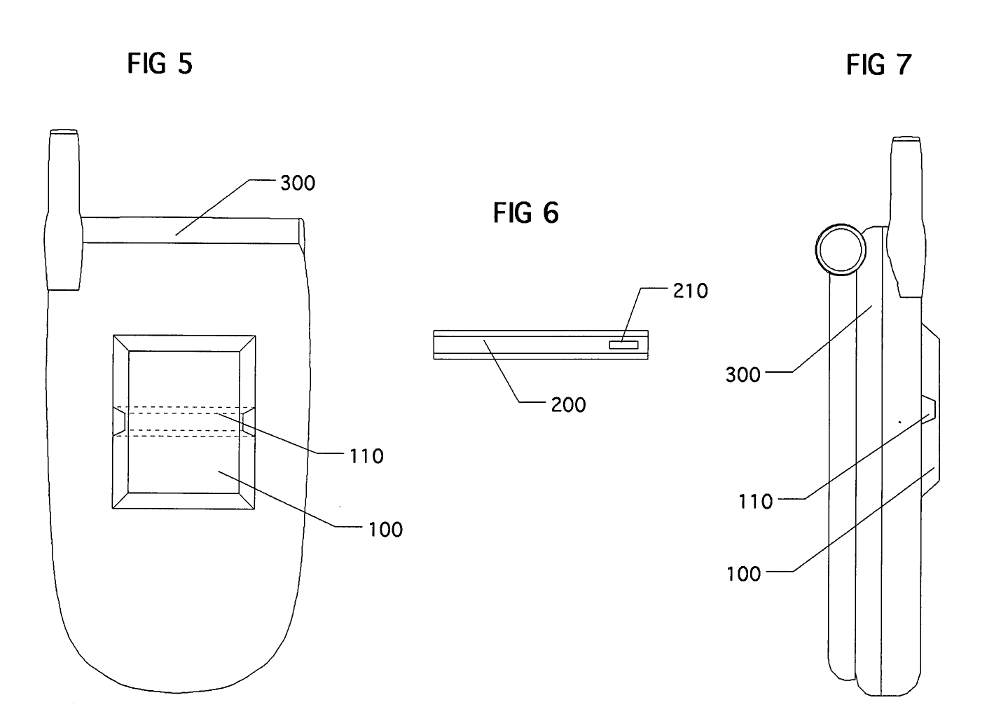

FIG. 5 is a top plan view of base plate 100 mounted on the backside of flip-style cellular telephone 300. FIG. 7 is a side elevation of base plate 100 mounted on the backside of flip-style cellular telephone 300. Base plate 100 is mounted in FIGS. 5 and 7 such that cavity 110 is oriented to run across the width of cellular telephone 300. The illustrated orientation facilitates use of the display enhancement device having mounting arms wrapping around either side of cellular telephone 300, thereby accommodating both left-handed and right-handed users. However, base plate 100 could readily be mounted with a differing orientation. For example, base plate 100 could be mounted such that cavity 110 runs parallel to the length of cellular telephone 300. Such a lengthwise orientation of cavity 110 would facilitate use of the device with support arms being wrapped around the top or bottom edge of cellular telephone 300. FIG. 6 is a top plan view of rigid mounting arm 200.

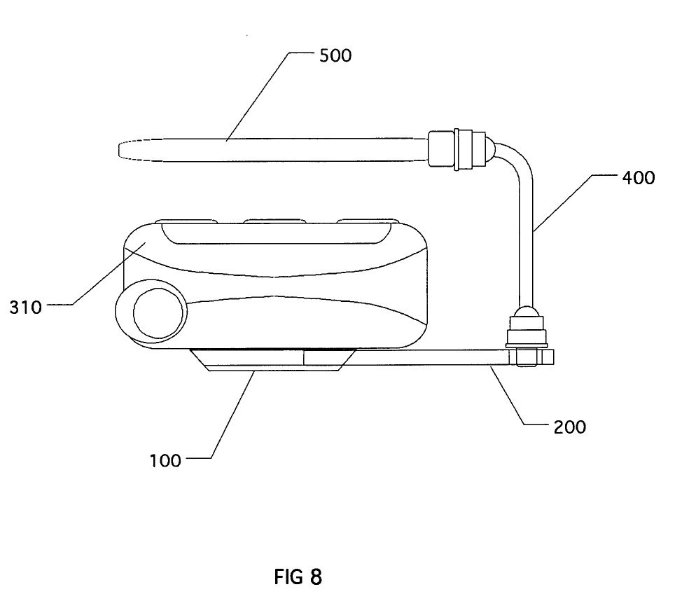

FIG. 8 is a front elevation view of a display enhancement device mounted on the backside of a cellular telephone 310. Mounting plate 100 is adhered to the back surface of telephone 310, with cavity 110 (not shown) being oriented across the width of cellular telephone 310. The end of rigid mounting arm 200 opposite slot 210 (not shown) is inserted partially into cavity 110, with the remaining portion of mounting arm 200 extending outward from the side of telephone 310.

Magnifying lens 500 is positioned above the display screen (not shown) of cellular telephone 310. In the embodiment illustrated, magnifying lens 500 is a Frenzel-type magnifying lens. Thus, the distance between lens 500 and cellular telephone 310 determines the amount by which the appearance of cellular telephone 310 is magnified. For example, lens 500 may be initially positioned 3 inches above the surface of cellular telephone 310. Lens 500 can then be positioned further away from cellular telephone 310 to provide greater magnification, or closer to cellular telephone 310 to provide a lesser level of magnification. The surface of lens 500 can be entirely transparent, or the surface can be partially printed with text and/or graphics, such as product designation, promotional and/or advertising material. While in the illustrated embodiment, lens 500 is a Frenzel-type magnifier, it is further envisioned that other types of lenses could be employed to enhance the viewing of a cellular telephone display or the like.

Magnifying lens 500 is attached to positioning arm 400, which is in turn attached to rigid mounting arm 200. Positioning arm 400 is attached to rigid mounting arm 200 via insertion into slot 210. Positioning arm 400 can be friction-fit into slot 210, or can be attached through other means such as adhesive. Positioning arm 400 is preferably comprised of a pliable non-elastic material, such as foam-coated or plastic-coated copper wire between 14 and 18 gauge in size, such that a user can orient lens 500 in a desired position above the display screen of cellular telephone 310.

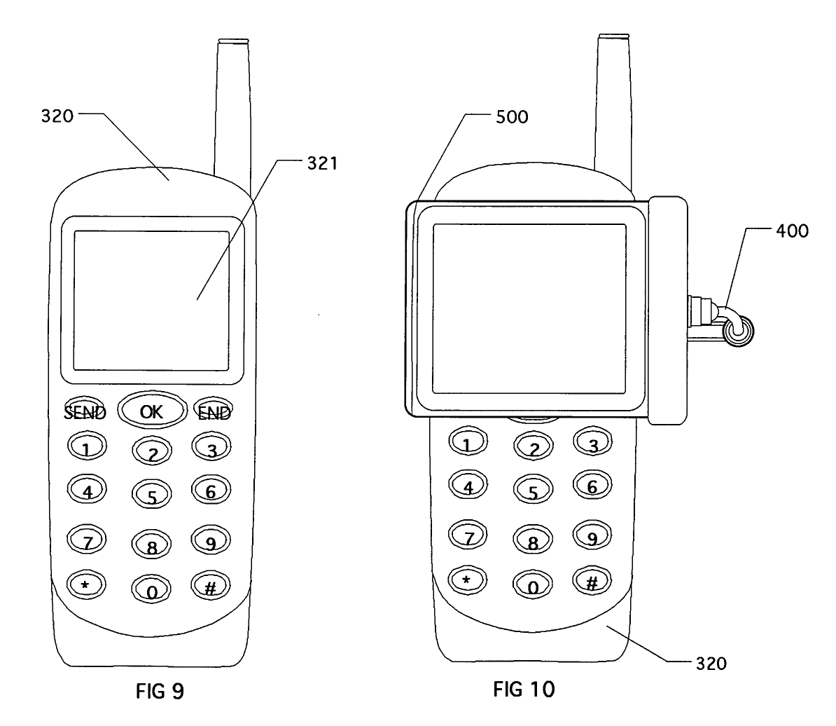

FIG. 9 is a top plan view of cellular telephone 320 having display screen 321, without a display enhancement device. FIG. 10 is a top plan view of cellular telephone 320 having a display enhancement device mounted thereon. Positioning arm 400 wraps around the side of cellular telephone 320, and retains magnifying lens 500 positioned above display screen 321. Thus, the image of display screen 321 can be viewed at an enlarged size on magnifying lens 500.

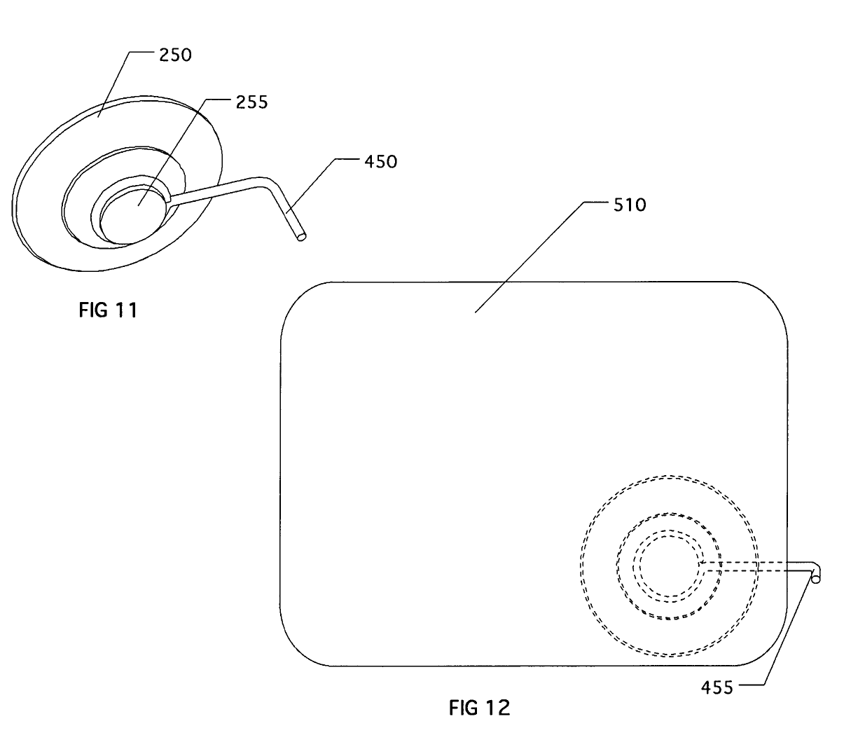

In another embodiment of the invention, a display enhancement device is provided which can be attached to a cellular telephone or the like through means other than a base plate. FIG. 11 is a perspective view of a suction cup mounting device 250. Suction cup 250 is provided with protuberance 255, to which positioning arm 450 is attached. Suction cup mounting bases may be desirable in certain applications, for which a rigid mounting base cannot be easily adhesively attached. For example, a suction cup mounting base can readily be attached to curvilinear surfaces of many cellular telephones, such as the flip-cover portion of many flip-style cellular telephones. Suction cup mounting bases can preferably be between 21 and 26 millimeters in diameter. Suction cup mounting bases may be comprised of transparent material, or can be colored.

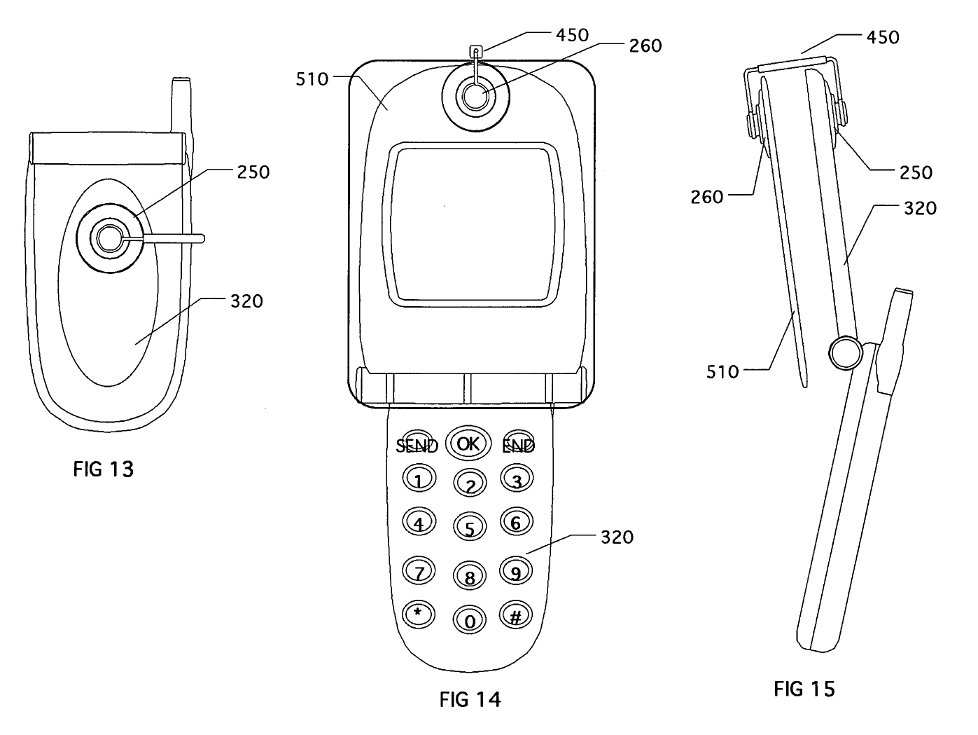

FIG. 12 is a top plan view of magnifier lens 510, having a suction cup mounting base (not shown) attached to the back surface of lens 510. Suction cup mounting bases attached to a lens are preferably transparent. Positioning arm 455 is attached to the suction cup mounting base positioned on the backside of lens 510.

FIG. 13 is a top plan view of flip-style cellular telephone 320 in a closed orientation, having suction cup mounting device 250 affixed to the flip-portion thereof.

FIG. 14 is a top plan view of flip-style cellular telephone 320 in an open orientation having a display enhancement device mounted thereto. FIG. 15 is a side elevation of the cellular telephone and display enhancement device of FIG. 14. Suction cup 250 is attached to the flip-portion of cellular telephone 320. Positioning arm 450 is attached to suction cup 250, as well as suction cup 260. Suction cup 260 is attached to magnifier lens 510. Lens 510 is positioned above cellular telephone display screen 321.

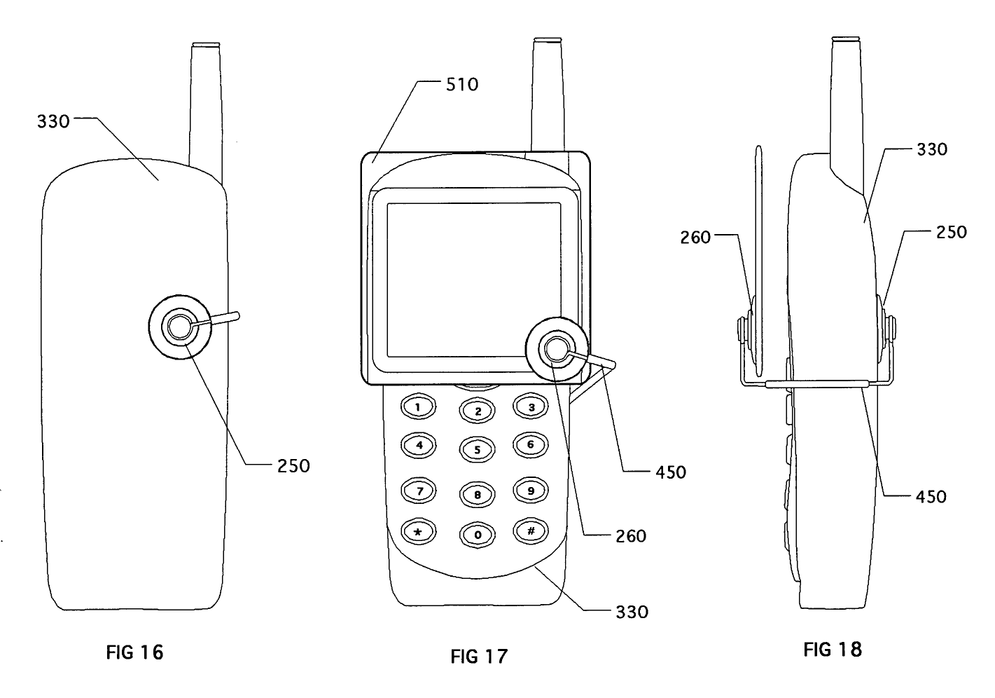

The display enhancement device having suction cup mounting bases can also be employed in connection with other styles of cellular telephone. FIG. 16 is a bottom plan view of candy bar style cellular telephone 330 having suction cup mounting device 250 attached thereto. FIGS. 17 and 18 illustrate the use of a display enhancement device with suction cup mounting bases attached to cellular telephone 330. In the top plan view of FIG. 17, positioning arm 450 is attached to the backside of cellular telephone 330 via suction cup 250 (not shown), and is oriented to wrap around the side of cellular telephone 330 to connect to suction cup 260 and lens 510, positioned above the cellular telephone display. FIG. 18 illustrates a side elevation of the arrangement of FIG. 17.

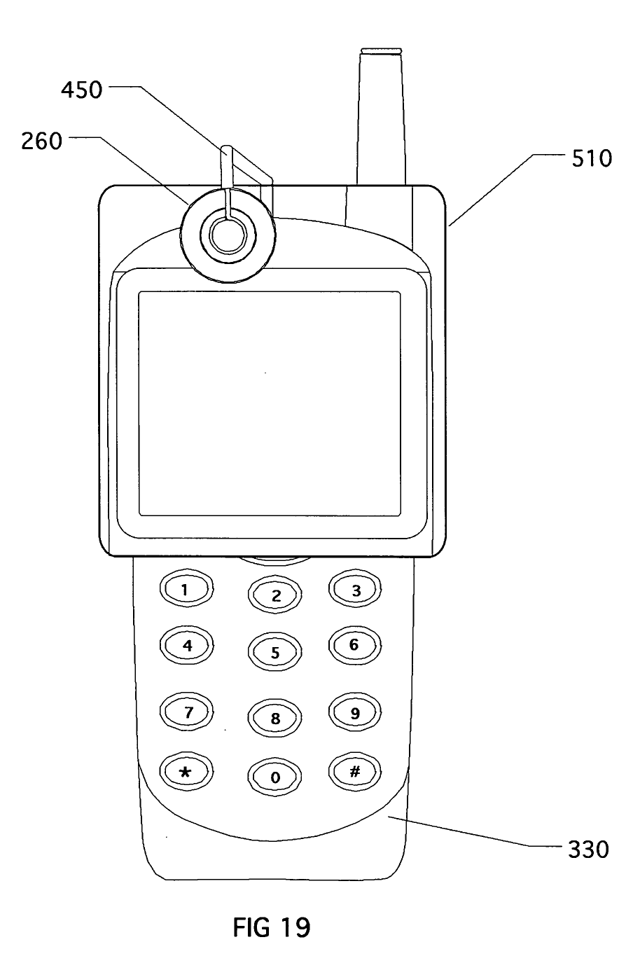

Due to the pliable and non-elastic characteristics of positioning arm 450, as well as the rotatable coupling between positioning arm 450 and suction cup bases 250 and 260, the position and orientation of the magnifying lens can be adjustably controlled by a user. FIG. 19 illustrates an alternative orientation for positioning arm 450. In FIG. 19, positioning arm 450 is wrapped over the top of cellular telephone 330.

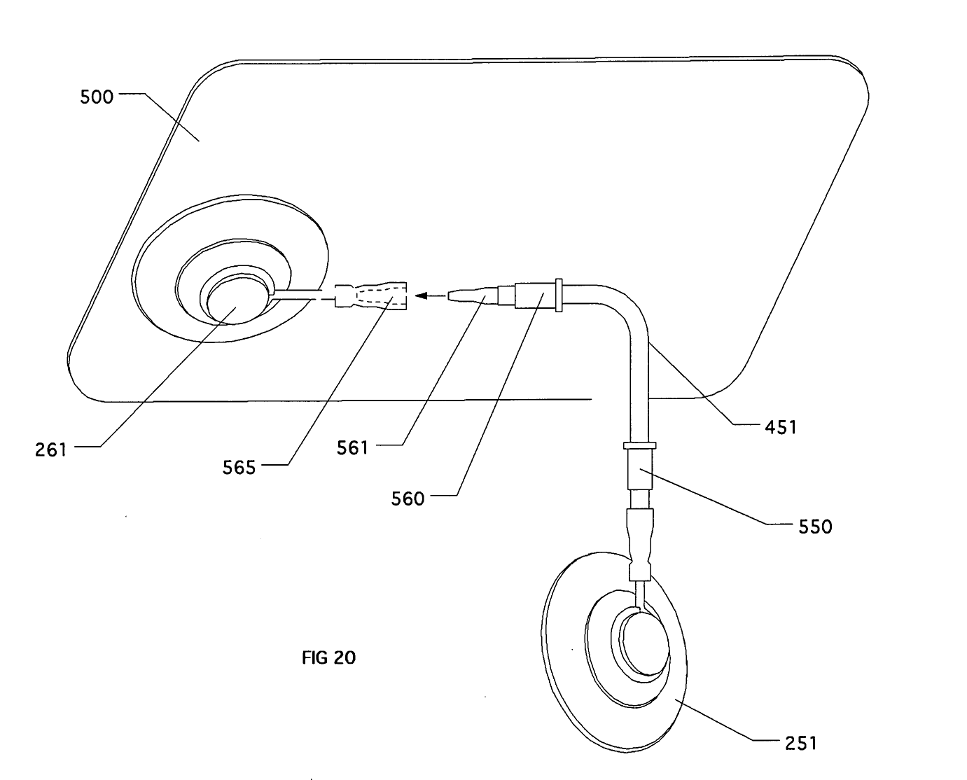

In accordance with another aspect of the invention, swivel joints can be used to facilitate adjustment of the orientation of a mounting arm and/or lens. FIG. 20 illustrates one embodiment of such a swivel joint interconnect. Positioning arm 451 is attached to suction cup mounting bases 251 and 261 via attachment mechanisms providing rotational adjustment between the positioning arm and each mounting base. Fixed connection swivel joint 550 provides a rotatable connection with mounting base 251, which mounting base can be detachably connected to the housing of a cellular telephone. Swivel joint 560 and snap connector 565 provide an alternative swivel joint mechanism providing detachable interconnection between positioning arm 451 and mounting base 261. Specifically, swivel joint 560 includes attachment tab 561 which is rotatable relative to positioning arm 451. Attachment tab 561 can be inserted into a void within snap connector 565 and removably secured thereto via a snap-fit connection. Snap connector 565 is attached to mounting base 261, which can be removably attached to magnifying lens 500. The swivel attachments of FIG. 20 provide increased flexibility with regard to positioning of magnifying lens 500 relative to the body of a cellular telephone. Thus, the magnifying lens can be readily adjusted to the angle of the cellular telephone display. While certain swivel designs are illustrated in the drawings, it is envisioned that alternative swivel joint designs could also be employed in connection with a display enhancement device according to the present invention.

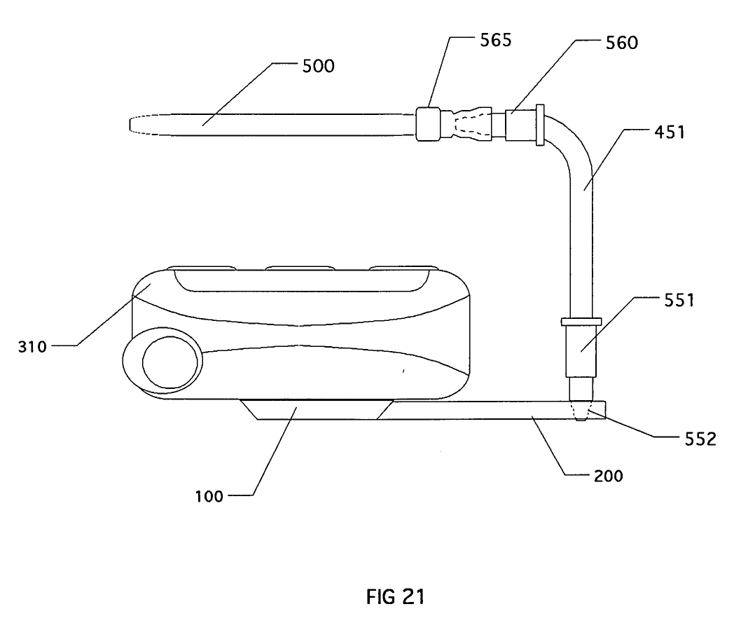

FIG. 21 is a diagram of a front elevation view of a display enhancement device having swivel joints, mounted on the backside of a cellular telephone using base plate 100. Base plate 100 is affixed to the rear surface of cellular telephone 310. Rigid mounting arm 200 is attached to base plate 100 and extends outward from the edge of cellular telephone 310. Swivel joint 551 includes mounting tab 552, which is adapted for removable insertion into slot 210 of arm 200. Positioning arm 451 is connected to swivel joint 551, as well as swivel joint 560. Swivel joint 560 can be removably attached to snap connector 565, which is attached to magnifying lens 500. Thus, the arrangement of FIG. 21 provides for flexible adjustment of magnifying lens 500 relative to the display of cellular telephone 310, such that viewing of the cellular telephone display is enhanced.

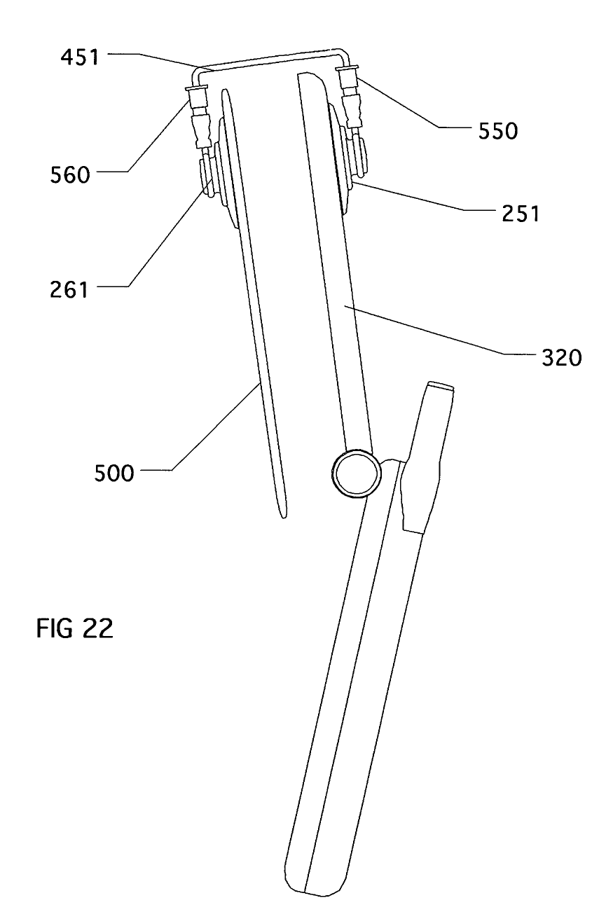

FIG. 22 is a side elevation of a flip-style cellular telephone in an open orientation having a display enhancement device with swivel joints mounted thereto. Suction cup mounting base 251 is removably mounted on the rear surface of a flip portion of flip-style cellular telephone 320. Mounting base 251 is attached to swivel joint 550. Swivel joint 550 is attached to one end of positioning arm 451. The other end of positioning arm 451 is attached to swivel joint 560 and, ultimately, suction cup mounting base 261. Magnifying lens 500 can be removably attached to suction cup mounting base 261, and positioned over the display of cellular telephone 320.

The foregoing description and drawings merely explain and illustrate the invention and the invention is not limited thereto, inasmuch as those skilled in the art, having the present disclosure before them will be able to make modifications and variations therein without departing from the scope of the invention

1. An apparatus for use with a portable electronic device having a visual display, the apparatus comprising:
a mounting mechanism attachable to the portable electronic device;
a magnifying lens;
a positioning arm having a first end and a second end, the positioning arm being attached at the first end to the mounting mechanism and attached at the second end to the magnifying lens.

2. The apparatus of claim 1, in which the magnifying lens is a Fresnel-type lens.

3. The apparatus of claim 1, in which the mounting mechanism is comprised of:
a mounting base that can be attached to the portable electronic device;
an elongated cavity within the mounting base and open to the exterior surface of the mounting base on at least one end;
a mounting arm comprised of an elongated member having a first end adapted for at least partial insertion into mounting base cavity and a second end attached to the positioning arm.

4. The apparatus of claim 3, in which the shape of at least a portion of the mounting arm cross-section is approximately the same as the shape of the cross section of the mounting base cavity, whereby the mounting arm is held in place by friction following its partial insertion into the cavity.

5. The apparatus of claim 4, in which the shapes of the cross-sections of the mounting base cavity and the mounting arm are approximately frusto-pyramidal.

6. The apparatus of claim 3, in which the mounting arm is rigid and the positioning arm is pliable.

7. The apparatus of claim 3, in which the mounting arm is further comprised of a slot into which the first end of the positioning arm can be inserted.

8. The apparatus of claim 1, in which the mounting base is approximately frusto-pyramidal in shape.

9. The apparatus of claim 1, in which the portable electronic device is a cellular telephone, and the mounting base is attached to the backside of the cellular telephone.

10. The apparatus of claim 3, in which the mounting base cavity extends completely through the interior of the mounting base such that the cavity is open to the exterior surface of the mounting base at two ends, whereby the mounting arm can be at least partially inserted into either open end of the cavity.

11. The apparatus of claim 9, in which the mounting arm wraps around the side of the cellular telephone to support the lens above a display on the front side of the cellular telephone.

12. The apparatus of claim 9, in which the mounting arm wraps over the top of the cellular telephone to support the lens above a display on the front side of the cellular telephone.

13. The apparatus of claim 1, in which the second end of the positioning arm is attached to the magnifying lens via a suction cup.

14. The apparatus of claim 1, in which the mounting mechanism is comprised of a suction cup.

15. The apparatus of claim 14, in which the second end of the positioning arm is attached to the magnifying lens via a suction cup.

16. The apparatus of claim 1, in which the positioning arm is connected to the mounting mechanism by a rotatable interconnect.

17. The apparatus of claim 7, in which the first end of the positioning arm comprises a rotatable tab adapted for insertion into the slot.

18. The apparatus of claim 1, in which the positioning arm is connected to the magnifying lens by a rotatable interconnect.

19. The apparatus of claim 18, in which the rotatable interconnect is comprised of a snap connector and a mounting tab which mounting tab can be removably attached to the snap connector, where one of the snap connector and mounting tab is attached to the positioning arm, and the other is attached to the lens.
